(19) United States
(12) Patent Application Publication
(10) Pub. No.: US 2024/0072125 A1
(43) Pub. Date: Feb. 29, 2024

(54) ELECTRONIC DEVICES WITH REDUCED OHMIC TO OHMIC DIMENSIONS

(71) Applicant: Wolfspeed, Inc., Durham, NC (US)

(72) Inventors: Kyle Bothe, Cary, NC (US); Evan Jones, Durham, NC (US); Chris Hardiman, Morrisville, NC (US)

(21) Appl. No.: 17/893,277

(22) Filed: Aug. 23, 2022

(51) Int. Cl. H01L 29/40; H01L 21/02; H01L 21/04; H01L 21/285; H01L 29/16; H01L 29/20; H01L 29/45

(52) U.S. Cl. CPC H01L 29/401; H01L 21/0217; H01L 21/0485; H01L 21/28575; H01L 29/1608; H01L 29/2003; H01L 29/45; H01L 29/452

(57) ABSTRACT

A method of forming ohmic contacts on a semiconductor layer includes forming silicon ohmic contact precursors on the semiconductor layer, depositing a layer of metal on the semiconductor layer including the silicon ohmic contact precursors, reacting the layer of metal with the silicon ohmic contact precursors to form metal silicide ohmic contacts on the semiconductor layer, and selectively removing the layer of metal from the semiconductor layer without removing the metal silicide contacts from the semiconductor layer.

### BACKGROUND

The present disclosure relates to transistor structures and in particular to planar field effect transistor devices having spaced apart ohmic contacts.

Narrow bandgap semiconductor materials, such as silicon (Si) and gallium arsenide (GaAs), are widely used in semiconductor devices for low power and, in the case of Si, low frequency applications. However, these semiconductor materials may not be well-suited for high power and/or high frequency applications, for example, due to their relatively small bandgaps (1.12 eV for Si and 1.42 for GaAs at room temperature) and relatively small breakdown voltages.

Interest in high power, high temperature and/or high frequency applications and devices has focused on wide bandgap semiconductor materials such as silicon carbide (3.2 eV for 4H—SiC at room temperature) and the Group III nitrides (e.g., 3.36 eV for GaN at room temperature). These materials may have higher electric field breakdown strengths and higher electron saturation velocities than GaAs and Si.

A device of particular interest for high power and/or high frequency applications is the High Electron Mobility Transistor (HEMT), which is also known as a modulation doped field effect transistor (MODFET). In a HEMT device, a two-dimensional electron gas (2DEG) may be formed at the heterojunction of two semiconductor materials with different bandgap energies, where the smaller bandgap material has a higher electron affinity than the wider bandgap material. The 2DEG is an accumulation layer in the undoped smaller bandgap material and can contain a relatively high sheet electron concentration, for example, in excess of 10¹³ carriers/cm 2. Additionally, electrons that originate in the wider bandgap semiconductor may transfer to the 2DEG, allowing a relatively high electron mobility due to reduced ionized impurity scattering. This combination of relatively high carrier concentration and carrier mobility can give the HEMT a relatively large transconductance and may provide a performance advantage over metal-semiconductor field effect transistors (MESFETS) for high-frequency applications.

HEMTs fabricated in the gallium nitride/aluminum gallium nitride (GaN/AlGaN) material system can generate large amounts of RF power due to a combination of material characteristics, such as relatively high breakdown fields, relatively wide bandgaps, relatively large conduction band offset, and/or relatively high saturated electron drift velocity. A major portion of the electrons in the 2DEG may be attributed to polarization in the AlGaN.

Field plates have been used to enhance the performance of GaN-based HEMTs at microwave frequencies and have exhibited performance improvement over devices without field plates. Many field plate approaches have involved a field plate connected to the source of the transistor with the field plate on top of the drain side of a channel. This can result in a reduction of the electric field on the gate-to-drain side of the transistor, thereby increasing breakdown voltage and reducing the high-field trapping effect. However, some transistors with gate-to-drain field plates can exhibit relatively poor reliability performance, particularly at class C (or higher class) operation where the electric field on the source side of the gate becomes significant.

FIG. 1 illustrates conventional operations for forming spaced apart source/drain contacts on a semiconductor layer. In particular, FIG. 1(a) illustrates a semiconductor layer 10 in which a pair of spaced-apart source/drain regions 12 are formed. The semiconductor layer 10 may include, but is not limited to, an epitaxial layer gallium nitride, a single-crystal silicon carbide substrate and/or an epitaxial layer of silicon carbide. The source/drain regions 12 may, for example be n+ regions formed by ion implantation into the semiconductor layer 10. To form source/drain ohmic contacts on the source/drain regions 12, first a lift-ff resist (LOR) 14 is coated onto the surface of the semiconductor layer 10 and soft baked.

Next, referring to FIG. 1(b), an imaging resist 16 is coated onto the LOR 14 and soft baked. Then, referring to FIG. 1(c), portions 16′ of the imaging resist 16 over the source drain regions 12 are exposed. Referring to FIG. 1(d), the exposed portions 16′ of the imaging resist 16 are developed, exposing the LOR 14 above the source/drain regions 12 and leaving a remaining portion of the LOR in place on the LOR 14. The LOR 14 is then developed, exposing the source/drain regions 12 and leaving a portion 14′ of the LOR beneath the remaining portion of the imaging resist 16. Because the LOR develops isotropically, the LOR forms an undercut beneath the remaining portion of the imaging resist 16, resulting in the bi-layer resist stack 22 shown in FIG. 1(d). The extent of the undercut is determined by the develop time of the LOR.

Referring to FIG. 1(e), a metal film 20, such as nickel or titanium, is then blanket deposited over the structure by evaporation. The metal film 20 is deposited on the source/drain regions 12 and also on the remaining portion of the imaging resist 16. The bi-layer structure of the resist stack 22 of the imaging resist 16 and remaining portion of LOR 14 ensures that the film deposition is discontinuous.

Referring to FIG. 1(f), the resist stack 22 is then lifted off, leaving portions of the metal film 20 in place on the source/drain regions 12. The metal film 20 may then be annealed to form source/drain ohmic contacts 24 on the source/drain regions 12.

### SUMMARY

A method of forming ohmic contacts on a semiconductor layer according to some embodiments includes forming silicon ohmic contact precursors on the semiconductor layer, depositing a layer of metal on the semiconductor layer including the silicon ohmic contact precursors, reacting the layer of metal with the silicon ohmic contact precursors to form metal silicide ohmic contacts on the semiconductor layer, and selectively removing the layer of metal from the semiconductor layer without removing the metal silicide contacts from the semiconductor layer. The semiconductor layer may include GaN or SiC.

The semiconductor layer may include a pair of spaced apart contact regions, and forming the silicon ohmic contact precursors may include depositing a layer of silicon on the semiconductor layer, wherein the layer of silicon covers the contact regions, and selectively removing portions of the layer of silicon outside the contact regions to form the silicon ohmic contact precursors.

The contact regions may be formed as n+ regions in the semiconductor layer.

In some embodiments, the metal silicide contacts are spaced apart on the semiconductor layer by a distance of less than 2 microns. In some embodiments, the metal silicide contacts are spaced apart on the semiconductor layer by a distance of about 0.4 to 1 microns.

In some embodiments, reacting the metal with the silicon ohmic contact precursors to form metal silicide contacts on the semiconductor layer may include annealing the semiconductor layer.

In some embodiments, the metal silicide contacts have a sheet resistance of less than about 3 ohms/square. The metal silicide contacts may have a vertical thickness above the semiconductor layer of less than about 200 nm. In some embodiments, the metal silicide contacts may have a vertical thickness above the semiconductor layer of about 100 nm to 200 nm.

The metal may include nickel, platinum and/or titanium. Selectively removing the metal layer from the semiconductor layer without removing the metal silicide contacts from the semiconductor layer may include performing a wet chemical etch of the metal layer.

The method may further include forming a protective layer on the semiconductor layer before forming the silicon ohmic contact precursors, wherein the protective layer may include SiN.

A method of forming ohmic contacts on a semiconductor layer including a pair of spaced apart contact regions according to some embodiments includes depositing a layer of silicon on the semiconductor layer, wherein the layer of silicon covers the contact regions, selectively removing portions of the layer of silicon outside the contact regions to form silicon ohmic contact precursors on the contact regions, depositing a layer of metal on the semiconductor layer including the silicon ohmic contact precursors, reacting the metal with the silicon ohmic contact precursors to form metal silicide contacts on the contact regions, and selectively removing the metal layer from the semiconductor layer without removing the metal silicide contacts from the contact regions.

An electronic device according to some embodiments includes a semiconductor layer, and a pair of ohmic contacts on the semiconductor layer, wherein the ohmic contacts are laterally spaced apart on the semiconductor layer by a distance of less than 2 microns. The semiconductor layer may include GaN or SiC.

The ohmic contacts may be spaced apart on the semiconductor layer by a distance of about 1 to 2 microns. In some embodiments, the ohmic contacts are spaced apart on the semiconductor layer by a distance of about 0.4 to 1 micron.

The ohmic contacts may include metal silicide contacts. The metal silicide contacts include NiSi, TiSi and/or PtSi. The metal silicide contacts may have a sheet resistance of less than about 3 ohms/square.

In some embodiments, the metal silicide contacts have a vertical thickness above the semiconductor layer of less than about 200 nm. In some embodiments, the metal silicide contacts are free of non-silicided portions of the metal.

### BRIEF DESCRIPTION OF THE DRAWINGS

FIG. 1 illustrates operations for forming contacts on a silicon carbide layer using a bi-layer resist stack.

FIG. 2 illustrates operations for forming contacts on a silicon carbide layer in accordance with some embodiments.

FIG. 3 is a scanning electron micrograph image of a layer on which a pair of adjacent ohmic contacts have been formed according to some embodiments.

FIG. 4 is a depth profile of the structure shown in FIG. 3 generated using a focused ion beam.

FIG. 5 is a flowchart illustrating operations according to some embodiments.

FIG. 6 illustrates a GaN-based high electron mobility transistor (HEMT) structure formed on a silicon carbide substrate including ohmic contacts formed according to some embodiments.

### DETAILED DESCRIPTION OF EMBODIMENTS

Embodiments of the inventive concepts will now be described in connection with the accompanying drawings.

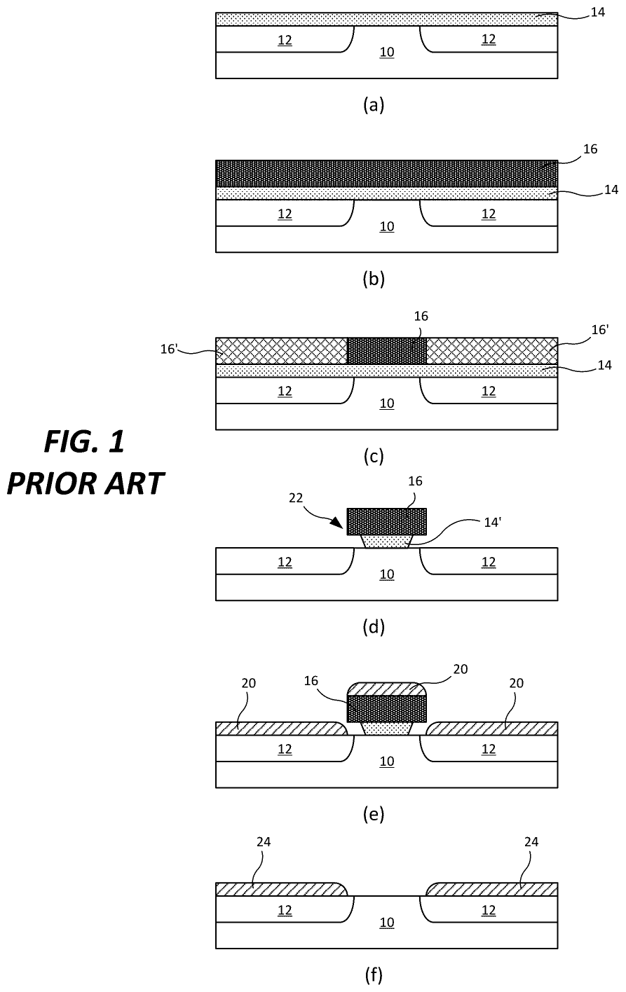

In the conventional approach to forming source/drain ohmic contacts 24 illustrated in FIG. 1, the lateral spacing between the source/drain ohmic contacts 24 is defined by the geometry of the bi-layer resist structure 22. The LOR 14′ portion of the resist stack 22 is not photo-defined, and the width of the LOR portion 14′ is strongly dependent on the develop time. Because of process variability, the process shown in FIG. 1 is not suitable for forming ohmic contacts with a lateral spacing between source/drain contacts of less than 2 microns.

Moreover, the method illustrated in FIG. 1 requires evaporated metal, resulting in edges that are not clean vertical features. The stem of the LOR 14′ and undercut of the bi-layer resist stack 22 may allow metal to be deposited in undesired locations between the source and drain regions 12. The amount of distance the metal may extend under the resist stack 22 depends on the variability of the photoresist material.

Other approaches, such as etching a metal stack, are possible, but have a potential for corrosion during the etch (such as in the case of Ni).

Some embodiments described herein provide a method of forming ohmic contacts on a silicon carbide layer having a pair of spaced apart contact regions that may address these or other deficiencies of conventional approaches. The method includes forming silicon ohmic contact precursors on the contact regions, and depositing a layer of metal on the silicon carbide layer including the silicon ohmic contact precursors. The layer of metal is reacted with the silicon ohmic contact precursors to form metal silicide ohmic contacts on the contact regions, and the layer of metal is selectively removed from the silicon carbide layer without removing the metal silicide contacts from the contact regions.

The silicon ohmic contacts are formed by forming a layer of silicon on the silicon carbide layer and patterning and etching the layer of silicon. By patterning and etching the silicon layer, the two ohmic metals can be brought closer together. The layer of metal is blanket deposited over the silicon ohmic contact precursors, which requires no alignment. When the un-reacted metal is removed, the resulting ohmic contacts are self-aligned. Such a process may work with any metal that forms a silicide, such as Ni, Ti, Pt, etc.

When the metal is Ni and NiSi ohmic contacts are formed, the remaining Ni can be removed with wet chemical etchants (e.g., HCl) which removes Ni and not the reactive NiSi.

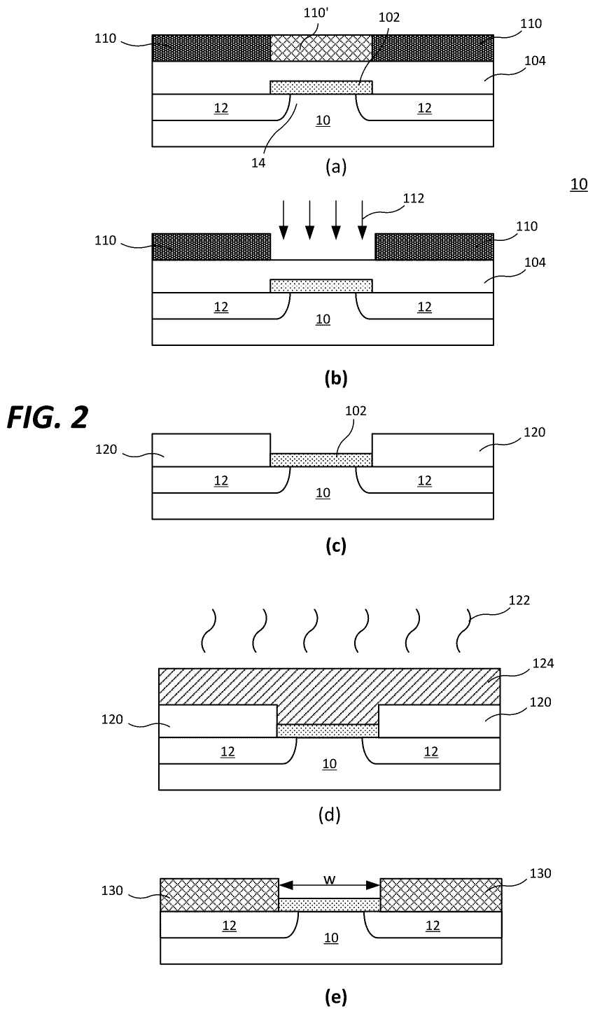

Operations for forming spaced-apart ohmic contacts to a silicon carbide layer are shown in FIG. 2. Referring to FIG. 2(a), a semiconductor layer 10 is provided. The semiconductor layer 10 may include, but is not limited to, an epitaxial layer of gallium nitride, a single crystal bulk silicon carbide substrate and/or a silicon carbide epitaxial layer. A silicon carbide layer may have a 2H, 4H, 6H or 3C polytype. A pair of spaced apart n+ source/drain regions 12 may be formed in the semiconductor layer 10, for example by ion implantation and annealing. The source/drain regions 12 define a channel region 14 in the layer semiconductor 10 between the source/drain regions 12.

An optional protective layer 102 may be formed on the layer semiconductor 10 in the channel region 14. The protective layer 102 may be formed of a material that provides an etch selectivity relative to silicon, and may, for example, include SiN.

A layer of silicon 104 is formed over the layer semiconductor 10, such as by evaporation or sputtering. An imaging photoresist layer 110 is formed on the layer 104 of silicon, and a portion of the imaging photoresist layer 110 above the channel region 14 is exposed to form an exposed portion 110′.

Referring to FIG. 2(b), the exposed portion 110′ of the imaging photoresist layer 110 is developed to exposed a portion of the layer 104 of silicon over the channel region 14. The exposed portion of the layer 104 of silicon is then anisotropically etched using a dry etch process 112, such as an inductively coupled plasma (ICP) etch, to remove a portion of the layer 104. In the etch process, the optional protective layer 102 may act as an etch stop layer if present.

Referring to FIG. 2(c), the remaining unexposed portion of the imaging resist 110 is removed, leaving silicon precursor structures 120 over the source/drain regions 12 of the semiconductor layer 10.

Referring to FIG. 2(d), a layer 124 of a metal that is capable of forming a silicide is blanket deposited over the substrate, such as by evaporation or sputtering, and then subjected to a heat treatment 122 at a temperature sufficient to cause the metal of the metal layer 124 to react with the silicon precursors 120 to form a metal silicide. The heat treatment may be performed at a temperature of greater than 400 C, and in some embodiments between 400 C and 800 C, to form the metal silicide. The layer 124 may be formed, for example, of nickel, platinum, titanium, tungsten, tantalum, or other metal that is capable of forming a silicide.

Referring to FIG. 2(e), following the heat treatment 122, the remaining unreacted portion of the metal layer 124 is removed, such as using a wet etch with HCl, leaving metal silicide contacts 130 on the source/drain regions 12 that are spaced apart by a lateral width w. By forming the metal silicide contacts 130 as described above, the lateral spacing of the metal silicide contacts 130 may be more accurately controlled compared to prior approaches. For example, the lateral spacing of the metal silicide contacts 130 may be limited only by the resolution of the photolithographic tools used to expose the imaging photoresist layer 110. In particular, in some embodiments, a lateral spacing w of less than 2 microns may be achieved. In some embodiments, the metal silicide contacts 130 may laterally spaced apart by a distance w of less than 1 micron, and in some embodiments less than 0.5 microns. In some embodiments, the metal silicide contacts 130 may laterally spaced apart by a distance w of between 0.4 microns and 1 micron.

The resulting ohmic contacts 130 may have a low sheet resistance. In particular, the ohmic contacts 130 may have a sheet resistance Rsh of about less than about 3 ohms/square, and in some embodiments of about 2.5 ohms/square.

The ability to carefully control the lateral spacing of the source/drain contacts may improve the reliability and/or stability of the manufacturing process for electronic devices, as it may produce devices with more consistent and/or precise ohmic contact spacing.

Moreover, it will be appreciated that in some embodiments, because the unreacted portion of the metal layer 124 is removed, the source/drain contacts 130 may be formed entirely of a metal silicide, which may have precise thickness control, as the thickness of the metal silicide forming the source/drain contacts 130 may be determined by the amount of silicon deposited on the semiconductor layer 10. In some embodiments, the metal silicide source/drain contacts 130 may have a thickness of less than 200 nm, in some embodiments about 100 nm to 200 nm, and in some embodiments about 150 nm.

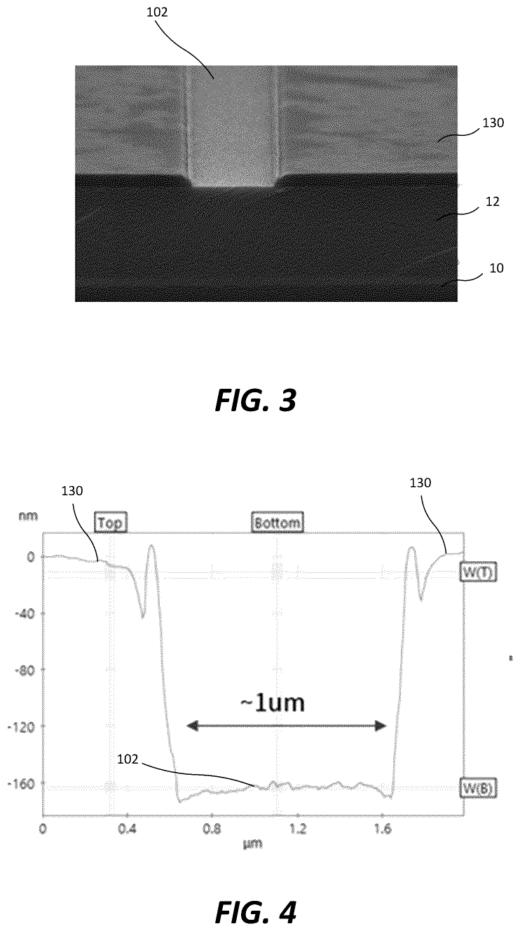

FIG. 3 is a scanning electron micrograph image of a semiconductor layer 10 including source/drain contact regions 12 on which a pair of adjacent ohmic contacts 130 have been precisely formed according to embodiments described herein. A protective SiN layer 102 is provided on the semiconductor layer 10 between the ohmic contacts 130.

FIG. 4 is a depth profile of the structure shown in FIG. 3 generated using a focused ion beam (FIB), showing a precisely controlled spacing of 1 micron between the ohmic contacts 130.

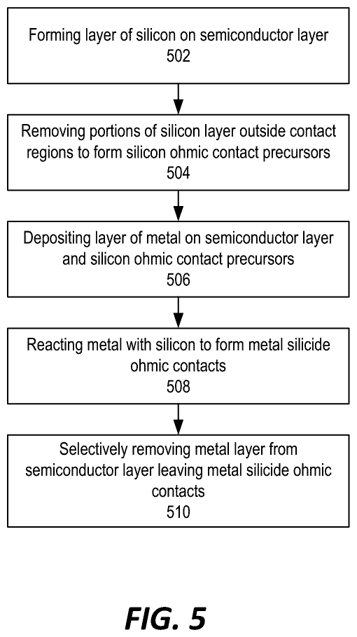

FIG. 5 is a flowchart illustrating operations according to some embodiments. Referring to FIG. 5, operations for forming ohmic contacts on a silicon carbide layer include forming silicon ohmic contact precursors on the silicon carbide layer. The silicon ohmic contact precursors may be formed by forming a layer of silicon on the silicon carbide layer (block 502) and removing portions of the silicon to form silicon ohmic contact precursors on the silicon carbide layer (block 504). A layer of metal is then deposited on the silicon carbide layer including the silicon ohmic contact precursors (block 506. The metal may be a metal such as Ni, Ti and/or Pt that forms a silicide. The layer of metal is reacted with the silicon ohmic contact precursors to form metal silicide ohmic contacts on the silicon carbide layer. The layer of metal is then selectively removed from the silicon carbide layer without removing the metal silicide contacts from the silicon carbide layer (block 510).

The silicon carbide layer may include a pair of spaced apart contact regions, and forming the silicon ohmic contact precursors may include depositing a layer of silicon on the silicon carbide layer, wherein the layer of silicon covers the contact regions, and selectively removing portions of the layer of silicon outside the contact regions to form the silicon ohmic contact precursors. The contact regions may be n+ regions in the silicon carbide layer.

The metal silicide contacts may be spaced apart on the silicon carbide layer by a distance of less than 2 microns. In some embodiments, the metal silicide contacts are spaced apart on the silicon carbide layer by a distance of about 0.4 to 2 microns.

Reacting the metal with the silicon ohmic contact precursors to form metal silicide contacts on the silicon carbide layer may be performed by annealing the silicon carbide layer.

In some embodiments, the metal silicide contacts may have a sheet resistance of less than about 3 ohms/square. The metal silicide contacts may have a vertical thickness above the silicon carbide layer of less than about 200 nm. In some embodiments, the metal silicide contacts have a vertical thickness above the silicon carbide layer of about 100 nm to 200 nm.

The metal layer may be selectively removed from the silicon carbide layer without removing the metal silicide contacts from the silicon carbide layer by performing a wet chemical etch of the metal layer.

In some embodiments, a protective layer, such as a layer of SiN, may be formed on the silicon carbide layer before forming the silicon ohmic contact precursors.

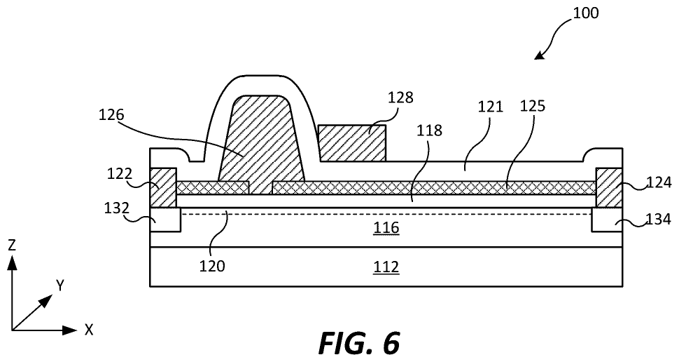

FIG. 6 shows a GaN-based high electron mobility transistor (HEMT) structure 100 on a silicon carbide substrate 112 including source and drain ohmic contacts 122, 124 formed according to some embodiments.

The HEMT structure 100 includes a GaN channel layer 116 on the substrate 112, and an AlGaN barrier layer 118 on the channel layer 116. A two dimensional electron gas (2DEG) 120 arises in the channel layer 116 adjacent the barrier layer 118. A source contact 122 and a drain contact 124 are formed on a source contact region 132 and a drain contact region 134 in the channel layer 116, respectively. The conductivity of the 2DEG 120 is modulated by applying a voltage to a gate 126 that is formed on the barrier layer 118 between the source contact 122 and the drain contact 124. As shown in FIG. 6, the gate 126 may have a mushroom or T-top configuration in which the gate 126 contacts the barrier layer 118 in a relative narrow contact region that extends through a surface dielectric layer 125.

The HEMT 100 includes a field plate 128 that is connected to the source contact 122. The field plate 128 is spaced apart from the gate 126 by an interlayer dielectric layer 121, and is spaced apart from the barrier layer 118 by the interlayer dielectric layer 121 and the surface dielectric layer 125. The field plate 128 extends above the gate 26 and laterally toward the drain 124.

The source contact 122 and drain contact 124 may be formed in accordance with the process described above with respect to FIGS. 2 and 5, and may be spaced apart laterally on the channel layer 116 by a distance of less than 2 microns, and in some embodiments less than 1 micron.

It will be understood that, although the ordinal terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Furthermore, relative terms, such as “lower” or “bottom” and “upper” or “top,” may be used herein to describe the relationship of one element to another as illustrated in the drawings. It is understood that relative terms are intended to encompass different orientations of the device in addition to the orientation depicted in the drawings. For example, if the device in one of the drawings is turned over, features described as being on the “lower” side of an element would then be oriented on “upper” side of that element. The exemplary term “lower” can therefore describe both lower and upper orientations, depending of the particular orientation of the device. Similarly, if the device in one of the drawings is turned over, elements described as “below” or “beneath” other elements would then be oriented above those other elements. The exemplary terms “below” or “beneath” can therefore describe both an orientation of above and below.

The terminology used in the description of the disclosure herein is for the purpose of describing particular embodiments only and is not intended to be limiting of the disclosure. As used in the description of the disclosure and the appended claims, the singular forms “an” and “the” are intended to include the plural forms as well, unless the context clearly indicates otherwise. It is also understood that the term “and/or” as used herein refers to and encompasses any and all possible combinations of one or more of the associated listed items. It will be further understood that the terms “comprises” and “comprising,” when used in this specification, specify the presence of stated steps, operations, features, elements, and/or components, but do not preclude the presence or addition of one or more other steps, operations, features, elements, components, and/or groups thereof.

Embodiments of the disclosure are described herein with reference to cross-section illustrations that are schematic illustrations of idealized embodiments of the disclosure. As such, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. The regions illustrated in the drawings are schematic in nature, and their shapes are not intended to illustrate the actual shape of a region of a device and are not intended to limit the scope of the disclosure unless explicitly stated otherwise. Further, lines that appear straight, horizontal, or vertical in the below drawings for schematic reasons will often be sloped, curved, non-horizontal, or non-vertical. Further, while the thicknesses of elements are meant to be schematic in nature.

Unless otherwise defined, all terms used in disclosing embodiments of the disclosure, including technical and scientific terms, have the same meaning as commonly understood by one of ordinary skill in the pertinent art and are not necessarily limited to the specific definitions known at the time of the present disclosure. Accordingly, these terms can include equivalent terms that are created after such time. It is further understood that terms, such as those defined in commonly used dictionaries, should be interpreted as having a meaning that is consistent with their meaning in the present specification and in the context of the relevant art.

Although embodiments of the inventive concepts have been described in considerable detail with reference to certain configurations thereof, other versions are possible. Accordingly, the spirit and scope of the invention should not be limited to the specific embodiments described above.

What is claimed is:

1. A method of forming ohmic contacts on a semiconductor layer, the method comprising:
forming silicon ohmic contact precursors on the semiconductor layer;
depositing a layer of metal on the semiconductor layer including the silicon ohmic contact precursors;
reacting the layer of metal with the silicon ohmic contact precursors to form metal silicide ohmic contacts on the semiconductor layer; and
selectively removing the layer of metal from the semiconductor layer without removing the metal silicide contacts from the semiconductor layer.

2. The method of claim 1, wherein the semiconductor layer comprises a pair of spaced apart contact regions, and wherein forming the silicon ohmic contact precursors comprises:
depositing a layer of silicon on the semiconductor layer, wherein the layer of silicon covers the contact regions; and
selectively removing portions of the layer of silicon outside the contact regions to form the silicon ohmic contact precursors.

3. The method of claim 2, wherein the contact regions comprise n+ regions in the semiconductor layer.

4. The method of claim 1, wherein the metal silicide contacts are spaced apart on the semiconductor layer by a distance of less than 2 microns.

5. The method of claim 1, wherein the metal silicide contacts are spaced apart on the semiconductor layer by a distance of about 0.4 to 1 microns.

6. The method of claim 1, wherein reacting the metal with the silicon ohmic contact precursors to form metal silicide contacts on the semiconductor layer comprises annealing the semiconductor layer.

7. The method of claim 1, wherein the metal silicide contacts have a sheet resistance of less than about 3 ohms/square.

8. The method of claim 1, wherein the metal silicide contacts have a vertical thickness above the semiconductor layer of less than about 200 nm.

9. The method of claim 1, wherein the metal silicide contacts have a vertical thickness above the semiconductor layer of about 100 nm to 200 nm.

10. The method of claim 1, wherein the metal comprises nickel.

11. The method of claim 1, wherein the metal comprises titanium.

12. The method of claim 1, wherein selectively removing the metal layer from the semiconductor layer without removing the metal silicide contacts from the semiconductor layer comprises performing a wet chemical etch of the metal layer.

13. The method of claim 1, further comprising forming a protective layer on the semiconductor layer before forming the silicon ohmic contact precursors, wherein the protective layer comprises SiN.

14. The method of claim 1, wherein the semiconductor layer comprises GaN.

15. The method of claim 1, wherein the semiconductor layer comprises SiC.

16. A method of forming ohmic contacts on a semiconductor layer comprising a pair of spaced apart contact regions, the method comprising:
depositing a layer of silicon on the semiconductor layer, wherein the layer of silicon covers the contact regions;
selectively removing portions of the layer of silicon outside the contact regions to form silicon ohmic contact precursors on the contact regions;
depositing a layer of metal on the semiconductor layer including the silicon ohmic contact precursors;
reacting the metal with the silicon ohmic contact precursors to form metal silicide contacts on the contact regions; and
selectively removing the metal layer from the semiconductor layer without removing the metal silicide contacts from the contact regions.

17. An electronic device, comprising:
a semiconductor layer; and
a pair of ohmic contacts on the semiconductor layer, wherein the ohmic contacts are laterally spaced apart on the semiconductor layer by a distance of less than 2 microns.

18. The electronic device of claim 17, wherein the ohmic contacts are spaced apart on the semiconductor layer by a distance of about 1 to 2 microns.

19. The electronic device of claim 17, wherein the ohmic contacts are spaced apart on the semiconductor layer by a distance of about 0.4 to 1 micron.

20. The electronic device of claim 17, wherein the ohmic contacts comprise metal silicide contacts.

21. The electronic device of claim 20, wherein the metal silicide contacts comprise NiSi.

22. The electronic device of claim 20, wherein the metal silicide contacts comprise TiSi.

23. The electronic device of claim 17, wherein the metal silicide contacts have a sheet resistance of less than about 3 ohms/square.

24. The electronic device of claim 17, wherein the metal silicide contacts have a vertical thickness above the semiconductor layer of less than about 200 nm.

25. The electronic device of claim 17, wherein the metal silicide contacts are free of non-silicided portions of the metal.

26. The electronic device of claim 17, wherein the semiconductor layer comprises GaN.

27. The electronic device of claim 17, wherein the semiconductor layer comprises SiC.
